(19) United States
(12) Patent Application Publication
(10) Pub. No.: US 2023/0396095 A1
(43) Pub. Date: Dec. 7, 2023

(54) Current Distribution Device Comprising A Load Detection Unit For Measuring A Detection Voltage

(71) Applicant: EUGEN FORSCHNER GMBH, Spaichingen (DE)

(72) Inventors: Peter RACZ, Spaichingen (DE); Jennifer STEGER, Spaichingen (DE)

(73) Assignee: EUGEN FORSCHNER GMBH, Spaichingen (DE)

(21) Appl. No.: 18/034,689

(22) PCT Filed: Oct. 26, 2021
(86) PCT No.: PCT/EP2021/079679

§ 371 Date: Apr. 29, 2023

(30) Foreign Application Priority Data
Oct. 30, 2020 (DE) 10 2020 128 701.1

(51) Int. Cl. H02J 13/00

(52) U.S. Cl. CPC H02J 13/00002

(57) ABSTRACT

This disclosure describes a current distribution device including a load detection unit for at least one electrical contact arranged on the load detection unit for measuring a detection voltage for checking an assignment of the contact. Within the current distribution device, the load detection unit is configured for a plurality of electrical contacts, each of which is provided with at least one switch connected in parallel with the contacts+, and wherein the load detection unit includes a respective resistor arranged in parallel pairwise with one of the switches, and wherein the parallel circuits are connected in series in the current direction of a test current. The present disclosure further relates to a method for measuring a detection voltage and to a use of a current distribution device.

### CROSS REFERENCE TO RELATED APPLICATIONS

This application is a national phase of international application PCT/EP2021/079679, filed 26 Oct. 2021, which claims the benefit of priority to German patent application 102020128701.1, filed Oct. 30, 2020, which the content of each of the aforementioned patent applications being incorporated herein by reference.

### BACKGROUND OF THE INVENTION

### Field of the Invention

The invention relates to a current distribution device comprising a load detection unit for measuring a detection voltage, a method comprising a current distribution device for measuring a detection voltage, and a use of a current distribution device for measuring a detection voltage.

### Description of Related Art

A current distribution device of the type is known from EP 3 022 816 B1. This is a direct current distribution system comprising a so-called load presence detection unit for detecting by means of a detection test voltage whether a contact of an electrical device has been connected to a terminal contact. In this case, the so-called load detection unit is designed in such a way that a detection test voltage is applied as a DC voltage to the contact and thus it is possible to measure whether the electrical device has been connected to the contact in the correct polarity by measuring a detection current at the contact. However, the measurement refers to only one electrical contact and also only to whether an electrical connection has been made at the contact. In this application, the term “contact” is intended to cover not only a single-pole connection, but also multi-pole connections.

### BRIEF SUMMARY OF THE INVENTION

The object of the invention is to provide a current distribution device with a load detection unit for measuring a detection voltage, by means of which different assignment combinations of a plurality of electrical contacts can be uniquely assigned to the measured detection voltage.

This object is solved according to the invention by a current distribution device with a load detection unit for measuring a detection voltage with the features according to claim 1, by a method for measuring a detection voltage with the features of claim 8 and by an advantageous use of such a current distribution device according to claim 10. Advantageous embodiments of the invention are given in the respective dependent claims.

A preferred field of application of the invention is applications in the automotive sector, in particular applications in electromobility. Thus, the current distribution device is preferably a current distribution device for high-voltage systems. High-voltage systems are systems that are operated with DC voltage above 60V up to 1.5 kV. In particular, when used in a vehicle, the high-voltage system has a corresponding high-voltage storage unit or a high-voltage battery.

With the present invention, it is possible to detect an individual assignment combination of the electrical contacts of a current distribution device by measuring the detection voltage of the load detection unit.

The current distribution device according to the invention comprises a load detection unit for at least one contact arranged on the load detection unit for measuring a detection voltage for checking an assignment of the contact. The load detection unit is thereby configured for a plurality of electrical contacts. Each of the contacts is provided with at least one switch, which is configured as a short-circuit bridge in the connector and establishes a conductive connection when the respective connector is plugged in. The load detection unit comprises a respective transistor arranged in parallel in pairs to one of the switches. Furthermore, the load detection unit preferably comprises a constant current source by means of which a test current is generated. The parallel circuits comprising the respective switch and the associated resistor are connected in series in the current direction of the generated test current. In particular, depending on the position of the switches in an open (O) or a closed (C) position, a constant test current (I) is thus conducted via the resistors of different strengths assigned to the open switches (O), while the resistors assigned to the closed switches (C) are bypassed, whereby in sum a unique detection voltage (U_{D}) can always be determined for the respective switching state of all switches.

This configuration enables the detection voltage to be measured in a simple and fast manner, the detection voltage being uniquely assignable to each possible assignment combination (O- or C-positions) of the electrical contacts.

A detailed description of an example of a current distribution device that can be used to implement the invention is provided in the applicant's DE 10 2018 132 988, the full disclosure of which is hereby also made the subject matter of the present patent application. In the present application, this current distribution device is not described in detail due to its minor importance for the actual invention.

Thus, the number of resistors (R1 to Rn) connected in the load detection unit is equal to the number of switches (S1 to Sn) connected in series, wherein each of the resistors (R1 to Rn) can also consist of several partial resistors connected in series. Thus, each switch is assigned exactly one unique resistor different from all other resistors. This circuit configuration makes it possible to determine for each resistor, depending on whether a switch is open (O=current flows via the resistor connected in parallel) or closed (C=current flows via the switch and not via the resistor connected in parallel), a partial voltage (U1 or U2 or U3 or Un) uniquely assigned to this switch or the resistor parallel thereto in the load detection unit. A partial total voltage (U_{GES1}) of this part of the load detection unit circuit can be determined as follows:

U_{GES1}=(U₁+U₂+U₃+Uₙ) with

U₁=R₁*I₁

U₂=R₂*I₂

U₃=R₃*I₃

Uₙ=Rₙ*Iₙ

In a particularly advantageous embodiment, a resistance value of for example a resistor (R2, R3, Rn) following a resistor (R1, R2, R3) in the current direction of the test current (I) corresponds to an integer multiple of a resistance value of the resistor (R1, R2, R3) preceding it. The order of arrangement of the resistors of different but respectively unique strengths with respect to the current direction is here only exemplary and by no means mandatory, so that the resistance values by no means only increase in the current direction, but the resistors of different strengths can be arranged in any sequence. The same applies to the number of four switches or four resistors assigned to them used in the embodiments of this application. It is understood by the person skilled in the art that the number of four switches and four resistors connected in parallel to them used in the described embodiment is chosen purely as an example and is in no way limiting for the invention. The invention can be used from a number of two switches or resistors assigned to them up to a large number of switches and resistors.

Particularly preferably, this resistance value of the following resistor corresponds to twice the resistance value of another resistor, for example the preceding resistor. In the embodiment example shown, the resistance value of the first resistor is 1 kOhm, that of the second resistor is 2 kOhm, that of the third resistor is 4 kOhm and that of the fourth resistor is 8 kOhm. In alternative embodiments, other resistance values may also be applied, taking into account the above condition of preferred integer doubling. The description of the resistors doubling as an integer in the direction of the current is by no means necessary, but merely facilitates compliance with a certain systematic approach, which in turn facilitates understanding of the invention.

Furthermore, the load detection unit according to the invention preferably comprises a compensating line to ground, whereby a further resistor (R₅) is assigned to this compensating line. Here, ground is considered the reference potential for the operating voltage (U_{GES}) of the load detection unit and has a value of zero. This corresponds to a voltage U₅ of 0 volts.

Thus, to determine the operating voltage (=total voltage) of the load detection unit, the voltage of the voltage dropping across the further resistor (U₅) of the compensating line must be added to the partial total voltage of the circuit configuration described above. Therefore:

U_{GES}=U_{GES1}+U₅, with

U₅=R₅*I₅

Of particular advantage is a variation of the load detection unit which comprises an operational amplifier configured as a differential amplifier, which is also referred to as a subtractor, wherein the respective operating voltage of the load detection unit is applied to a first input (+) of the operational amplifier and the voltage dropping across the resistor (R5) is applied to a second input (−). An output voltage generated in this way at the output of the operational amplifier corresponds to the detection voltage of the load detection unit. According to the invention, a differential amplifier with a transit frequency of 1 MHz is used, which thus generates a gain of 1. The output voltage can be calculated with the formula:

U_{D}=U_{A}=U_{GES}−U₅

with
U_{D}=detection voltage
U_{A}=output voltage at the operational amplifier
U_{GES}=total voltage
U₅=voltage at R5

The method according to the invention with a current distribution device, which comprises a load detection unit for at least one electrical contact arranged on the load detection unit, is used for measuring a detection voltage of the load detection unit for checking a present assignment of all existing contacts with corresponding, not shown, plugs.

The load detection unit is configured for a large number of electrical contacts and the electrical contacts are each connected to a switch, the number of contacts thus corresponding to the number of switches. The contacts are connected to their assigned switches in such a way that when a plug is inserted into the respective contact, the switch assigned to this contact is actuated mechanically or by a switching bridge arranged on the plug into the closed position. When the plug is removed from the contact, the switch is then reopened.

In addition, the load detection unit comprises a plurality of resistors each arranged in parallel with one of the switches. Here, the detection voltage can be measured by means of a voltage or current detection unit. The voltage or current detection unit is formed, for example, by an operational amplifier configured as a differential amplifier, at the output of which the detection voltage value, which can be uniquely assigned to the respective switching state of all switches as a sum, can be measured. The amount of the detection voltage can thus be uniquely assigned to any assignment of the open or closed switches (=assignment combination) and thus also to the electrical contacts assigned to the switches.

The detection voltage can be determined individually for each assignment combination using the formulas already described. In the case of the four-switch arrangement described below as an example, there are thus 4²=16 different assignment combinations and thus unique detection voltages for the four electrical contacts (see FIG. 5).

### BRIEF DESCRIPTION OF THE SEVERAL VIEWS OF THE DRAWINGS

Further advantages, features, and details of the various embodiments of this disclosure will become apparent from the ensuring description of a preferred exemplary embodiment and with the aid of the drawings. The features and combinations of features recited below in the description, as well as the features and feature combination shown after that in the drawing description or in the drawings alone, may be used not only in the particular combination received, but also in other combinations on their own, without departing from the scope of the disclosure.

In the following, an embodiment of the invention is explained in more detail with reference to the figures, wherein:

FIG. 1 depicts a schematic view of a current distribution device with four electrical contacts;

FIG. 2 depicts a circuit diagram of a first assignment combination of the load detection unit with interrupted power supply for self-diagnosis;

FIG. 3 depicts a circuit diagram of the first assignment combination of the load detection unit with two open switches—but without interruption of the power supply;

FIG. 4 depicts a circuit diagram of a second assignment combination of the load detection unit with three open switches; and

FIG. 5 depicts a table with 4²=16 assignment combinations of the electrical contacts with the corresponding detection voltages.

### DETAILED DESCRIPTION OF THE INVENTION

As used throughout the present disclosure, unless specifically stated otherwise, the term “or” encompasses all possible combinations, except where infeasible. For example, the expression “A or B” shall mean A alone, B alone, or A and B together. If it is stated that a component includes “A, B or C”, then, unless specifically stated otherwise or infeasible, the component may include A, or B, or C, or A and B, or A and C, or B and C, or A and B and C. Expressions such as “at least one of” do not necessarily modify an entirety of the following list and do not necessarily modify each member of the list, such that at least one of “A, B, and C” should not be understood as including only one of A, only one of B, only one of C, or any combination of A, B, and C.

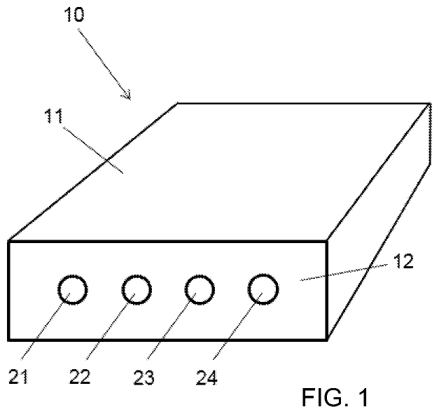

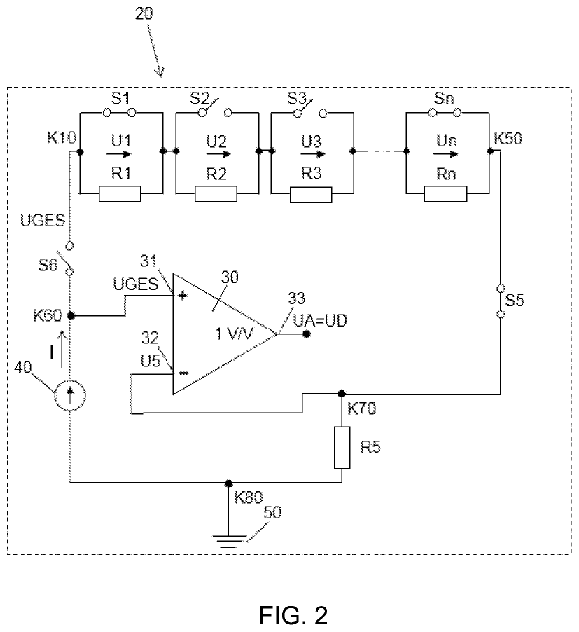

FIG. 1 shows a schematic view of a current distribution device 10 with electrical contacts 21, 22, 23 and 24 arranged on one side 12 of a housing 11. A load detection unit 20 (see FIGS. 2 to 4) is arranged inside the housing 11. A detailed description of an embodiment example of a basic configuration of a current distribution device 10 is explained in DE 10 2018 132 988 of the same applicant and is not included in the present application due to its minor importance for the present invention.

In the first circuit diagram of a switch configuration of the load detection unit 20 shown in FIG. 2, switches S1, S2, S3 and Sn are assigned to the electrical contacts 21, 22, 23 and 24 (see FIG. 1). The switches S1, S2, S3 and Sn are arranged in series as a so-called series circuit. Switches S1, S2, S3 and Sn are each assigned a resistor R1, R2, R3 and Rn in parallel circuit.

In the embodiment shown, the resistor R1 assigned to the first switch S1 has a resistance value of 1 kOhm, the resistor R2 assigned to the second switch S2 has a resistance value of 2 kOhm, the resistor R3 assigned to the third switch S3 has a resistance value of 4 kOhm, and the resistor Rn assigned to the fourth switch Sn has a resistance value of 8 kOhm. Thus, the resistance value of a resistor R2, R3 and Rn following in a current direction I corresponds to an integer multiple of the resistance value of a resistor R1, R2 and R3 preceding it. In the example of the load detection unit according to the invention shown, the integer multiple is twice the value of the resistor preceding it in each case. As already mentioned in the introduction to the description, neither the number 4 for switches and resistors is to be regarded as limiting, but merely exemplary, nor the size of the resistors R1, R2, R3 and Rn, their arrangement in the direction of current or their integer multiple with respect to each other. What is essential is that a plurality (>2 . . . n) of switches, which can be arranged in any order, are each assigned unique and different resistors.

An operational amplifier 30 forming the voltage or current detection unit in the embodiment shown has a first input 31 and a second input 32, as well as an output 33. The potential at the first input 31 is an operating or total voltage U_{GES} of the load detection unit corresponding to the current I of a constant current source 40, and the potential at the second input 32 is a partial voltage U₅ which drops across the resistor R5.

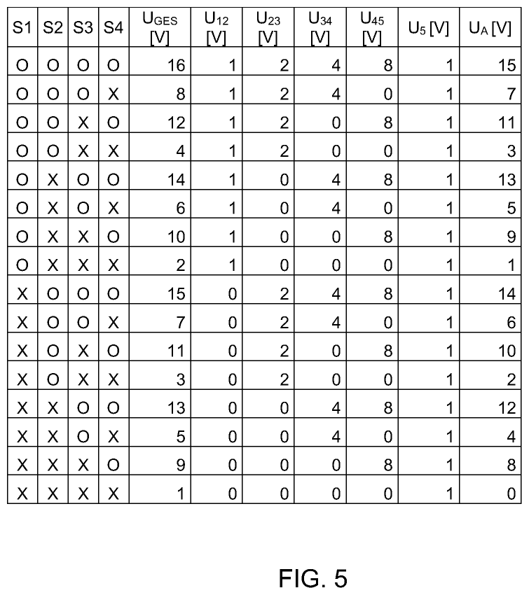

The operational amplifier 30 used as an example in the load detection unit 20 according to the invention is a differential amplifier—also called a subtractor. This means that the voltage U₅ applied to the second input 32 is subtracted from the voltage U_{GES} applied to the first input 31. A resulting output voltage U_{A} can be measured at output 33. This output voltage U_{A} corresponds to a detection voltage U_{D} which can be uniquely assigned to an assignment combination of the switches S1, S2, S3 and Sn. The detection voltages U_{D} associated with the possible assignment combinations of the load detection unit 20 according to the invention can be taken from FIG. 5. An example of a calculation can be found in the description of FIG. 5.

Starting from a constant current source 40, a test current I is directed to switches S1 to Sn via a node 60 and a disconnector S6. At node 60, a branch is provided to the first input 31 of the operational amplifier 30.

Switch S6, which is located above constant current source 40 in FIG. 2, is shown open here. This means that the measuring circuit is interrupted and thus no current flows in the load detection unit 20, which also means that no output voltage U_{A} or detection voltage U_{D} can be measured. The measurement circuit interruption by the open switch S6 is used, for example, for self-diagnosis of the load detection unit 20 or for simulating a cable break.

At a node 10, switches S1, S2, S3, and Sn follow in an upper branch of the network, and resistors R1, R2, R3, and Rn connect in a lower branch of the network. Switches S1, S2, S3 and Sn and resistors R2, R2, R3 and Rn are each connected pairwise in parallel (S1 with R1, S2 with R2, . . . , Sn with Rn).

This series connection of several parallel arrangements (S1 with R1, S2 with R2, . . . , Sn with Rn) is followed by a node K50 with a subsequent switch S5. From a node K70 following in the further course in current direction of the measuring current I a compensating line with a node K80 branches off to ground 50, to which a further resistor R5 is assigned. Here, ground 50 is the reference potential for the operating voltage of the load detection unit 20.

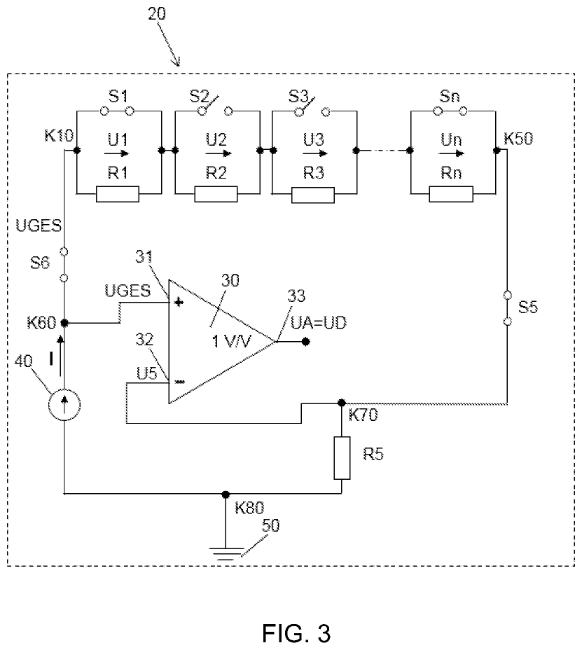

In the switch configuration shown in FIG. 3 with closed switches S1 and Sn (corresponding to contacts 21 and 24 provided with plugs) and open switches S2 and S3, the test current I flows from the voltage source 40 in current direction I via node K60 and closed switch S6, via node K10 and closed switch S1, further via resistor R2, resistor R3 and switch Sn to node K50. From there, the test current I flows further via a closed switch S5 as well as via node K70 and from there on to the second input 32 of the operational amplifier 30. The detection voltage U_{D} to be measured is thus 6 volts in this example (with R2=2 kOhm and R3=4 kOhm) and the required operating voltage (total voltage) U_{GES} is 7 volts. Both values can be taken from the table in FIG. 5 in the seventh row from the bottom.

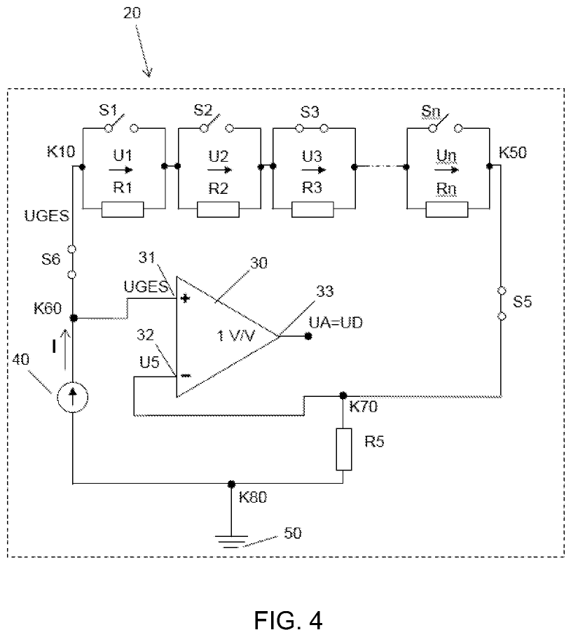

FIG. 4 shows a second possible assignment combination of switches S1, S2, S3 and Sn, where only switch S3 is closed (correspondingly contact 23 is connected to a plug) and the other three switches S1, S2 and Sn are open. Here, as already described above, current I flows through node 60, closed switch S6, and node K10. Since switch S1 is open, the current now flows through resistor R1. Since switch S2 is also open, current also flows through resistor R2 and then through closed switch S3, bypassing resistor R3. Since the switch Sn is open, the current then continues to flow via the resistor Rn to the node K50. The further course is analogous to the description in FIG. 3. The detection voltage U_{D} to be measured for this assignment combination is thus (with R1=1 kOhm, R2=2 kOhm and Rn=8 kOhm) 11 volts and the required operating voltage U_{GES} 12 volts. These values can also be taken from the table in FIG. 5 in the third data line from the top.

The table shown in FIG. 5 gives an overview of the different assignment combinations of the electrical contacts 21, 22, 23, 24 and thus to the respective positions of the switches S1, S2, S3, Sn. The switch Sn is designated as S4 in FIG. 5, as is the resistor Rn as R4. While the index “n” indicates an arbitrarily large number of switches and resistors, the index “4” refers to the finite number of exemplary four of these elements in each case in the embodiment shown.

Here, in FIG. 5, the character “O” applies to the “open” state and the character “C” applies to the “closed” state. With the four electrical contacts 21, 22, 23, 24 to be checked in the embodiment shown, there are thus 4²=16 different assignment combinations for the electrical contacts 21, 22, 23 and 24 of the load detection unit 20.

The detection voltage U_{D} can be uniquely assigned to each individual assignment combination. For example, an assignment combination in which switches S1 and S2 are closed (=C) and switches S3 and S4 are open (=O) results in an output voltage U_{A} at operational amplifier 30 of 12 volts. Since the detection voltage U_{D} corresponds to the output voltage U_{A}, this is also 12 volts. This results from the formulas already used above:

U_{D}=U_{A}=U_{GES}−U₅, wherein

U_{GES}=U_{GES1}+U₅ with

U_{GES1}=U₁+U₂+U₃+U₄ and

U₃=R₃*I₃=4 kOhm*1 mA=4V,

U₄=R₄*I₄=8 kOhm*1 mA=8V and

U₅=R₅*I₅=1 KOhm*1 mA=1V.

The dropping voltage at U₁ and U₂ is 0 volts, because the two switches S1, S2—as mentioned above—are closed and therefore the current can flow unhindered.

In the reference signs used in FIGS. 2 to 4, the indices have not been subscripted for the sake of readability.

Since the devices and methods described in detail above are examples of embodiments, they can be modified to a wide extent by the skilled person in the usual manner without departing from the scope of the invention. In particular, the mechanical arrangements and the proportions of the individual elements with respect to each other are merely exemplary. Some preferred embodiments of the apparatus according to the invention have been disclosed above. The invention is not limited to the solutions explained above, but the innovative solutions can be applied in different ways within the limits set out by the claims.

1. A current distribution device, comprising:
a load detection unit comprising at least one electrical contact, and configured to measure a voltage across the at least one electrical contact and to determine whether the at least one electrical contact is open or closed based upon the voltage; and wherein:
the load detection unit is configured to make a plurality of electrical contacts, each of the electrical contacts being provided with at least one switch connected in parallel with the contacts;
the load detection unit comprises a resistor assigned to each of the switches;
wherein each resistor is arranged in parallel and paired with a corresponding switch so as to form a parallel circuit; and
each parallel circuit is connected in series in a current direction of a test current with another parallel circuit.

2. The current distribution device according to claim 1, wherein the resistance values of each of the resistors corresponds to a unique integer multiple of another resistance value.

3. The current distribution device according to claim 2, wherein:
a resistance value of a resistor is twice a resistance value of another resistor, and
each resistance value occurs only once.

4. The current distribution device according to claim 1, wherein the load detection unit comprises a voltage or current detection unit.

5. The current distribution device according to claim 4, wherein the voltage or current detection unit comprises an operational amplifier designed as a differential amplifier.

6. The current distribution device according to claim 5, wherein the voltage or current detection unit is configured to determine a unique measurement value correlating to the position of the plurality of switches.

7. The current distribution device according to claim 1, wherein the load detection unit comprises a constant current source configured to provide the test current.

8. The current distribution device according to claim 1, wherein the current distribution device is a current distribution device for a high-voltage system.

9. A method for measuring a detection voltage of a load detection unit arranged in a current distribution device, the method comprising the steps of:
using the load detection unit to check an assignment of at least one electrical contact arranged on the load detection unit,
configuring the load detection unit to facilitate a plurality of electrical contacts formed by a plurality of switches,
arranging on the load detection unit a plurality of resistors pairwise and in parallel with a corresponding one of the switches, and
configuring a detection voltage which is unique due to a different assignment of the contacts being measurable at a voltage or current detection unit.

10. The method according to claim 9, wherein each of the resistance values of the resistors, starting from a first smallest resistance value, doubles for one of the other resistors up to a maximum resistance value, the test current having to pass through the resistor assigned to a respective one of the switches when the respective switch is open and, as a result, the amount of the detection voltage of an assignment of the opened or closed switch and thus also the electrical contact assigned to the switches is uniquely assignable.

11. (canceled)
